(19) United States
(12) Patent Application Publication
(10) Pub. No.: US 2018/0204904 A1
(43) Pub. Date: Jul. 19, 2018

(54) METHOD OF MANUFACTURING SEMICONDUCTOR DEVICE

(71) Applicants: Kabushiki Kaisha Toshiba, Minato-ku (JP); Toshiba Infrastructure Systems & Solutions Corporation, Kawasaki-shi (JP)

(72) Inventor: Shigeki YOSHIDA, Kawasaki (JP)

(73) Assignees: Kabushiki Kaisha Toshiba, Minato-ku (JP); Toshiba Infrastructure Systems & Solutions Corporation, Kawasaki-shi (JP)

(21) Appl. No.: 15/700,340

(22) Filed: Sep. 11, 2017

(30) Foreign Application Priority Data
Jan. 19, 2017 (JP) 2017-007429

(51) Int. Cl. H01L 49/02; H01L 21/311; H01L 27/06

(52) U.S. Cl. CPC H01L 28/40; H01L 27/0629; H01L 21/31111

(57) ABSTRACT

In a method of manufacturing a semiconductor device, a first insulation film is formed in a first region and a second region on a semiconductor substrate by covering an active element provided in the first region on the semiconductor substrate, a second insulation film is formed on the first insulation film, and a part of the second insulation film corresponding to the first region is removed through a predetermined etching process to expose the first insulation film corresponding to the removed part. An etching selectivity between the first insulation film and the second insulation film is set such that the second insulation film is removed, and the first insulation film remains through the etching process.

### CROSS-REFERENCE TO RELATED APPLICATION

This application is based upon and claims the benefit of priority from Japanese Patent Application No. 2017-007429 filed on Jan. 19, 2017, the entire contents of which are incorporated herein by reference.

### FIELD

Embodiments described herein relate generally to a method of manufacturing a semiconductor device.

### BACKGROUND

As a technique for optimizing a high-frequency signal processing or miniaturizing the entire semiconductor device, there is known a technique of forming a semiconductor device using a monolithic microwave integrated circuit (MMIC). In the MMIC, both an active element such as a field effect transistor (FET) and a passive element such as a capacitor are arranged on the same semiconductor substrate.

As a technique relating to the MMIC, Patent Document 1 discusses a method of manufacturing a semiconductor device within a short time by simultaneously forming the FET and the capacitor in the same step.

However, in the semiconductor device manufactured in this method, thicknesses of insulation films formed on the FET (active element) and the capacitor (passive element) become equal to each other. For this reason, the insulation film that covers a surface of the FET is thickened more than necessary depending on a specification of the capacitor (for example, a thickness of an interlayer insulation film), and this disadvantageously degrades a high-frequency characteristic of the FET.

### BRIEF DESCRIPTION OF THE DRAWINGS

FIG. 1 is a schematic diagram illustrating a configuration of the semiconductor device according to an embodiment of the present disclosure;

FIG. 2 is a flowchart illustrating a semiconductor device manufacturing steps according to an embodiment;

FIG. 3A is a diagram illustrating a first procedure of manufacturing a semiconductor device according to an embodiment;

FIG. 3B is a diagram illustrating a second procedure of manufacturing the semiconductor device according to an embodiment;

FIG. 3C is a diagram illustrating a third procedure of manufacturing the semiconductor device according to an embodiment;

FIG. 3D is a diagram illustrating a fourth procedure of manufacturing the semiconductor device according to an embodiment;

FIG. 3E is a diagram illustrating a fifth procedure of manufacturing the semiconductor device according to an embodiment;

FIG. 4A is a diagram illustrating a first procedure of manufacturing a semiconductor device according to a modification of the present disclosure;

FIG. 4B is a diagram illustrating a second procedure of manufacturing the semiconductor device according to a modification of the present disclosure;

FIG. 4C is a diagram illustrating a third procedure of manufacturing the semiconductor device according to a modification of the present disclosure;

FIG. 4D is a diagram illustrating a fourth procedure of manufacturing the semiconductor device according to a modification of the present disclosure; and

FIG. 4E is a diagram illustrating a fifth procedure of manufacturing the semiconductor device according to a modification of the present disclosure.

### DETAILED DESCRIPTION

A semiconductor device and a method of manufacturing the semiconductor device according to an embodiment of the present disclosure will now be described with reference to the accompanying drawings. The semiconductor device according to this embodiment is a high-frequency device provided with a monolithic microwave integrated circuit (MMIC).

As illustrated in FIG. 1, the semiconductor device 1 includes a semiconductor substrate 100, an active element 10, a passive element 20, a first insulation film 30, and a second insulation film 40.

The semiconductor substrate 100 includes a substrate 11 and a semiconductor layer 12. The substrate 11 is formed of, for example, silicon (Si), silicon carbide (SiC), or the like.

The semiconductor layer 12 includes an electron transport layer 12a and a barrier layer 12b. The electron transport layer 12a is formed of gallium nitride (GaN), gallium arsenide (GaAs), or the like and is laminated on the substrate 11. The barrier layer 12b is formed of aluminum gallium nitride (AlGaN), indium aluminum gallium nitride (InAlGaN), or the like, and is laminated on the electron transport layer 12a.

The barrier layer 12b has a bandgap larger than that of the electron transport layer 12a and forms a heterojunction structure along with the electron transport layer 12a. In addition, the barrier layer 12b has an implantation layer where impurity atoms (dopant) are implanted. The implantation layer is formed such that a peak of the concentration of the impurity atoms is located in the vicinity of an interface with the electron transport layer 12a, and a part thereof is also formed in the electron transport layer 12a. As a result, a region (2-DEG channel) where a two-dimensional electron gas (2-DEG) is generated is provided in an interface between the electron transport layer 12a and the barrier layer 12b.

The active element 10 is formed in a first region R1 (active element region) of the semiconductor substrate 100. The first region R1 is set as an area for forming the active element 10 in advance. The active element 10 is an element that performs active operation such as amplification or rectification, and specifically includes a transistor, a diode, and the like. The active element 10 of FIG. 1 is a metal oxide semiconductor field effect transistor (MOSFET) or a field effect transistor (FET) having a high electron mobility transistor (HEMT) structure.

The passive element 20 is formed in a second region R2 (passive element region) of the semiconductor substrate 100. The second region R2 is set as an area for forming the passive element 20 in advance. The passive element 20 is an element that performs passive operation such as accumulation, consumption, or discharging of the supplied power, and specifically includes a capacitor, a resistor, a coil, and the like. The passive element 20 of FIG. 1 is a metal insulator metal (MIM) capacitor.

The first insulation film 30 is provided in common with the active element region R1 and the passive element region R2 of the semiconductor substrate 100. The first insulation film 30 covers and protects the active element 10 in the active element region R1. In addition, the first insulation film 30 underlies the passive element 20 in the passive element region R2 to serve as a protection film (passivation film) for protecting the semiconductor substrate 100 (barrier layer 12b) of the passive element region R2. The first insulation film 30 has a thickness so as not to degrade a high-frequency characteristic of the active element 10.

The second insulation film 40 overlies the first insulation film 30 of the passive element region R2. In addition, the second insulation film 40 is not provided over the insulation film 30 of the active element region R1. The second insulation film 40 of FIG. 1 serves as an interlayer insulation film of the MIM capacitor. In addition, an etching selectivity between the first and second insulation films 30 and 40 is set such that the second insulation film 40 is removed through a predetermined etching process, and the first insulation film 30 remains without being removed. The second insulation film 40 has at an etch rate higher than that of the first insulation film 30.

Specifically, the first and second insulation films 30 and 40 are formed of the same insulation material such as silicon nitride (SiN) or silicon dioxide (SiO₂) using different formation techniques. For example, the first insulation film 30 is formed using an atomic layer deposition (ALD) technique, and the second insulation film 40 is formed using a plasma chemical vapor deposition (PCVD) technique. Since the ALD and the PCVD are different insulation film formation techniques, the resulting insulation films also have a difference in film quality. As a result, in a case where a predetermined etching process using a liquid or gas is applied to the first and second insulation films 30 and 40, only the second insulation film 40 is removed, and the first insulation film 30 remains.

As described below, the second insulation film 40 is formed in the active element region R1 as well as the passive element region R2 in the course of the manufacturing. However, the second insulation film 40 formed in the active element region R1 is selectively removed (etched). For this reason, a surface of the active element 10 is covered only by the first insulation film 30 as illustrated in FIG. 1, so that the first insulation film 30 is exposed.

Subsequently, a configuration of the active element 10 (FET) will be descried. The active element 10 is provided in the active element region R1 on the semiconductor substrate 100 and has a dielectric layer 13, a source 14s, a gate 14g, and a drain 14d.

The dielectric layer 13 is formed of an insulation material such as silicon nitride (SiN) or silicon dioxide (SiO₂). The dielectric layer 13 is laminated on the semiconductor layer 12 (barrier layer 12b) of the active element region R1.

The gate 14g is interposed between the source 14s and the drain 14d and is provided on the barrier layer 12b. The gate 14g has a contact base portion 141 and a field plate 142.

The contact base portion 141 is provided in the center of the bottom of the gate 14g. The contact base portion 141 is formed on a surface of the barrier layer 12b to make a shottky contact with the barrier layer 12b. Note that a gate insulation film may be formed between the contact base portion 141 and the barrier layer 12b. The contact base portion 141 adjusts a flow of electrons between the source 14s and the drain 14d by controlling a 2-DEG channel provided in an interface between the electron transport layer 12a and the barrier layer 12b.

The field plate 142 is provided to protrude toward the source 14s and the drain 14d from the contact base portion 141 in an eave shape. The dielectric layer 13 is provided between the field plate 142 and the barrier layer 12b to alleviate concentration of electric fields in the contact base portion 141.

The gate 14g is interposed between the source 14s and the drain 14d, and the source 14s and the drain 14d are formed on a surface of the barrier layer 12b to make an ohmic contact with the barrier layer 12b. The source 14s and the drain 14d are provided by interposing the gate 14g and dielectric layer 13.

The surfaces of the dielectric layer 13, the source 14s, the gate 14g, and the drain 14d are covered by the first insulation film 30. That is, the first insulation film 30 provided in the active element region R1 serves as a protection film for protecting the surface of the active element 10.

Meanwhile, the passive element 20 (MIM capacitor) is provided in the passive element region R2 on the semiconductor substrate 100 and has a lower electrode 21 and an upper electrode 22. The first insulation film 30 serving as a passivation film underlies the lower electrode 21. In addition, the second insulation film 40 serving as the interlayer insulation film is provided between the lower electrode 21 and the upper electrode 22.

Manufacturing steps of the semiconductor device 1 configured as described above generally includes the following four steps:
(1) a step of forming the first insulation film 30 in the active element region R1 and the passive element region R2;
(2) a step of forming the second insulation film 40 in the active element region R1 and the passive element region R2;
(3) a step of removing the second insulation film 40 formed in the active element region R1; and
(4) a step of forming the passive element 20 in the passive element region R2.

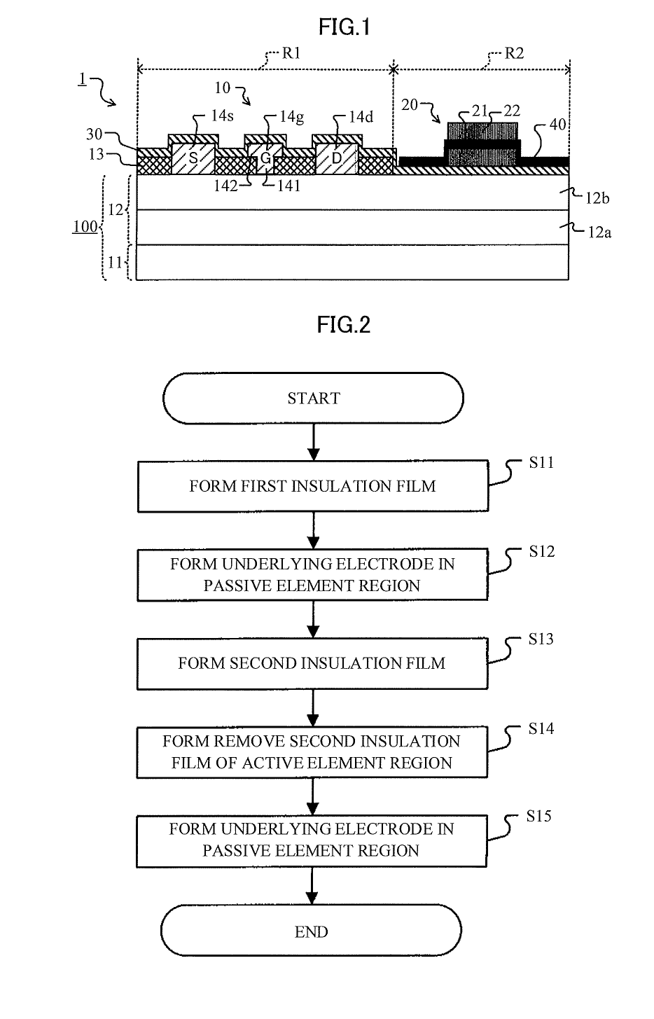

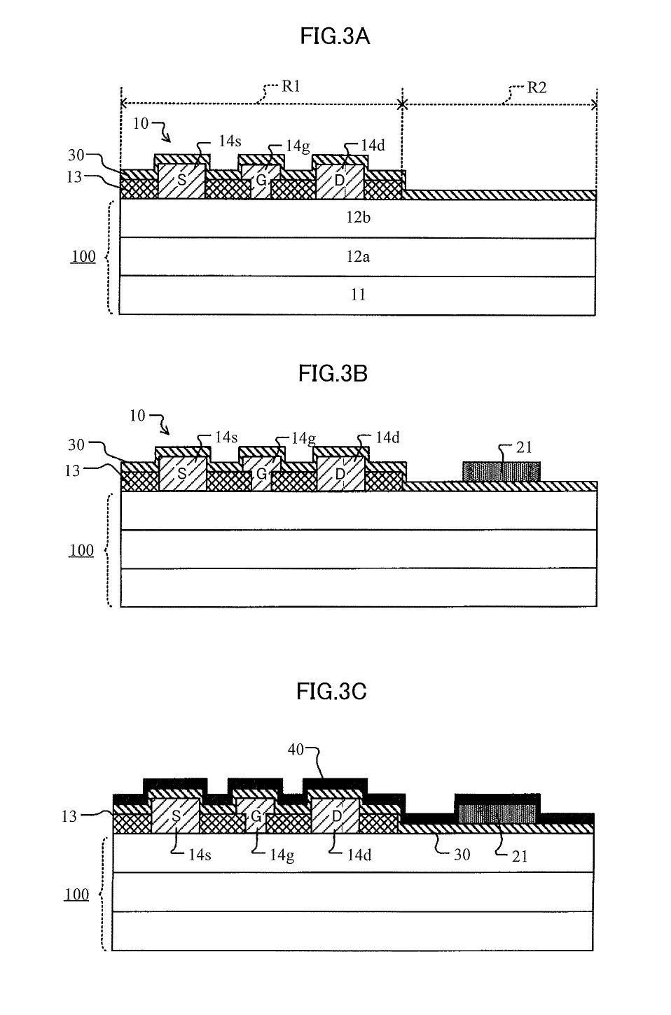

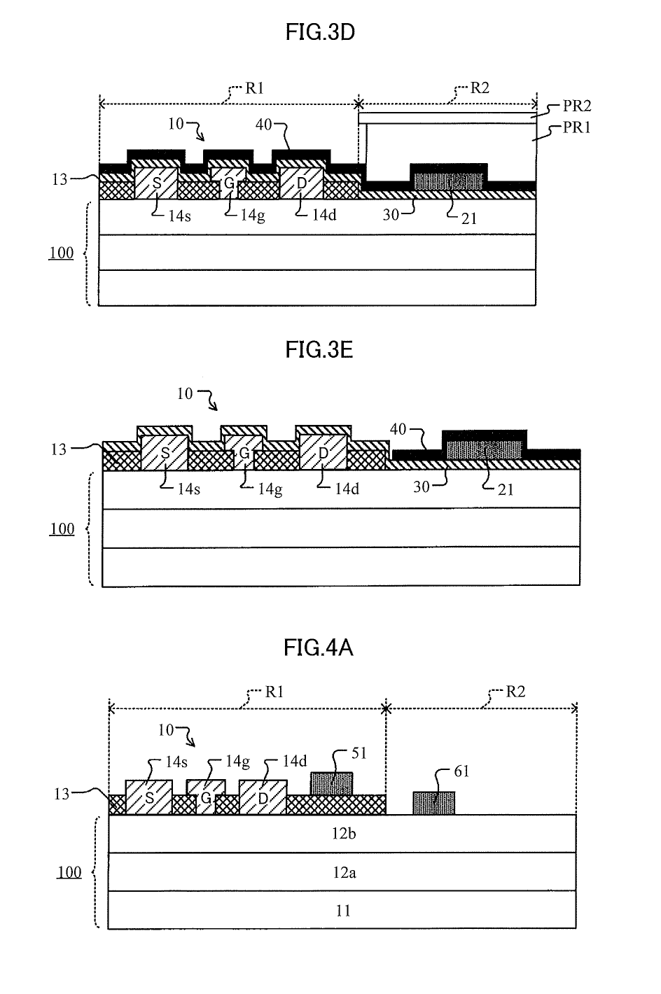

The manufacturing steps of the semiconductor device 1 will now be described details with reference to FIGS. 2 and 3A to 3E.

As illustrated in FIG. 3A, the first insulation film 30 is continuously formed in the active element region R1 and the passive element region R2 (on the entire surface) on the semiconductor substrate 100 provided with the active element 10 (first insulation film formation step, step S11 of FIG. 2). The first insulation film 30 is formed using an ALD technique. The first insulation film 30 covers the surface of the active element 10 in the active element region R1. The first insulation film 30 covers the surface of the semiconductor substrate 100 (barrier layer 12b) in the passive element region R2.

After the first insulation film 30 is formed, the lower electrode 21 of the passive element 20 is patterned in the passive element region R2, for example, through photolithography or the like as illustrated in FIG. 3B (step S12 of FIG. 2).

After the lower electrode 21 is formed, the second insulation film 40 is formed (second insulation film formation step, step S13 of FIG. 2). The second insulation film 40 is continuously formed on the first insulation film 30 in the active element region R1 and the passive element region R2 (the entire surface) as illustrated in FIG. 3C. The second insulation film 40 is formed using the PCVD technique.

Then, the second insulation film 40 formed in the active element region R1 is removed (insulation film exposure step, step S14 of FIG. 2). For example, a pair of resist layers PR1 and PR2 are patterned on the second insulation film 40 formed in the passive element region R2 as illustrated in FIG. 3D, and etching using a predetermined liquid or gas is performed for the active element region R1. Through this process, only the second insulation film 40 is removed from the active element region R1, and the first insulation film 30 remains and is exposed as illustrated in FIG. 3E.

Then, the upper electrode 22 opposite to the lower electrode 21 is patterned on the second insulation film 40 serving as an interlayer insulation film, for example, through photolithography or the like (step S15 of FIG. 2). As a result, the passive element 20 is formed in the passive element region R2.

Through the aforementioned steps, the semiconductor device 1 of FIG. 1 is manufactured.

As described above, according to the present disclosure, the first insulation film 30 is formed using a film formation technique different from that of the second insulation film 40. An etching selectivity between the first and second insulation films 30 and 40 is set such that only the second insulation film 40 is removed, and the first insulation film 30 remains without be removed through the predetermined etching process. For this reason, using the manufacturing steps, the first and second insulation films 30 and 40 can be simultaneously formed in the active element region R1 and the passive element region R2, respectively. Then, the second insulation film 40 formed in the active element region R1 can be selectively removed. As a result, it is possible to form an insulation film (first insulation film 30) that does not degrade the high-frequency characteristic of the active element 10. In addition, it is possible to effectively form the first and second insulation films 30 and 40 of the semiconductor device 1.

Note that an example in which the first insulation film 30 is provided through the ALD technique, and the second insulation film 40 is provided through a PCVD technique has been described in the aforementioned embodiment. However, the etching selectivity between the first and second insulation films 30 and 40 may set such that only the second insulation film 40 is removed, and the first insulation film 30 remains through the etching process. For this reason, any other film formation technique may also be employed in combination. For example, the first insulation film 30 may be formed using a vacuum ALD technique, and the second insulation film 40 may be formed using a vacuum CVD technique or a vacuum physical vapor deposition (PVD) technique. The first and second insulation films 30 and 40 may be formed of different insulation materials using the same or different film formation technique(s) so as to provide the etching selectivity described above.

An example in which the active element 10 is the FET, and the passive element 20 is an MIM capacitor has been described in the aforementioned embodiment. Alternatively, any other active element 10 (such as a diode) or passive element 20 (such as a resistor or a coil) may also be employed.

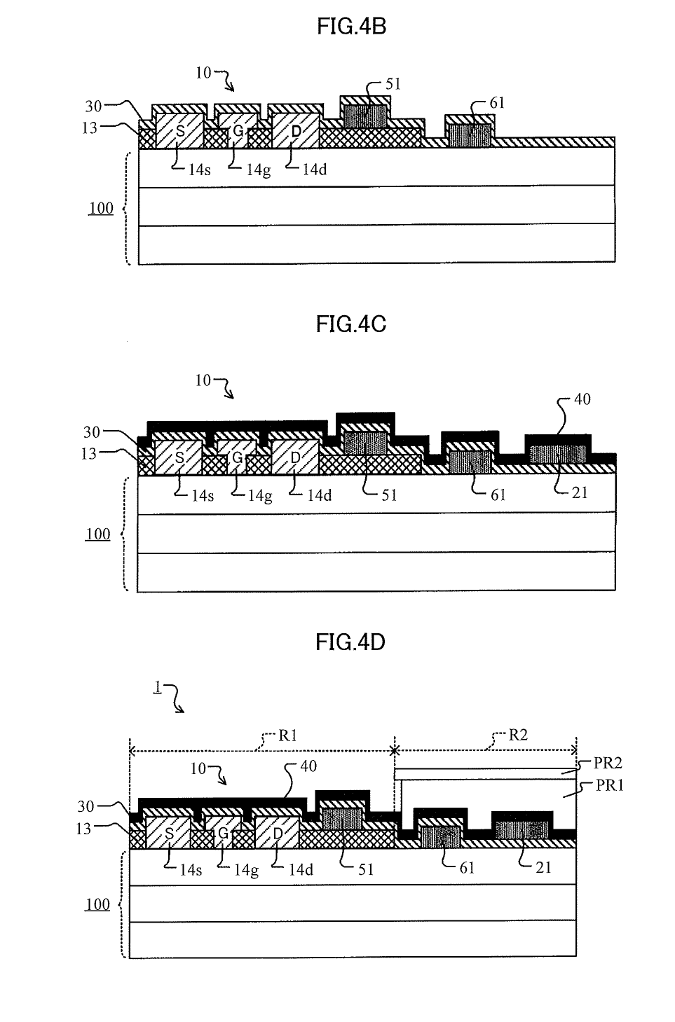

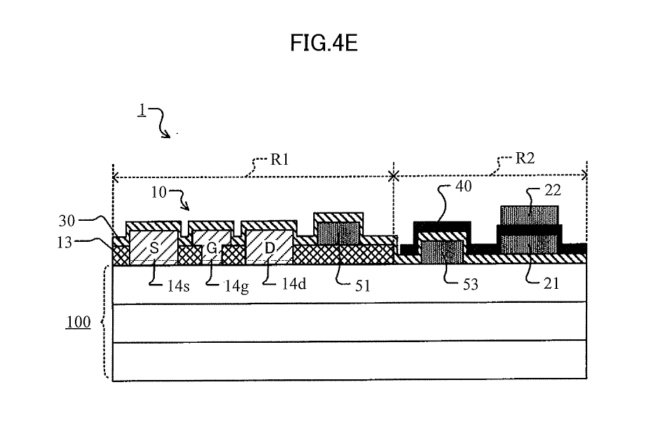

As illustrated in FIG. 4A, an element other than the active element 10 or an element such as a part of the passive element 20 may also be provided before the first insulation film 30 is provided. For example, an element 51 is provided on the dielectric layer 13 of the active element region R1, and an element 61 is provided on the semiconductor layer 12 of the passive element region R2 (between the substrate 11 and the first insulation film 30). Even in this case, the semiconductor device 1 is manufactured through the steps similar to the aforementioned embodiment as illustrated in FIGS. 4B to 4E.

While several embodiments have been described hereinbefore, such embodiments are just for illustrative purposes, and are not intended to limit the scope of the invention. Such embodiments may be embodied in various other forms, and various omissions, substitutions, and modification may be possible without departing from the spirit and scope of the invention. Such embodiments and modifications encompass the inventions described in the claims and their equivalents within the sprit and scope of the invention.

What is claimed is:

1. A method of manufacturing a semiconductor device, the method comprising:
forming a first insulation film in a first region and a second region on a semiconductor substrate by covering an active element provided in the first region on the semiconductor substrate;
forming a second insulation film on the formed first insulation film; and
removing a part of the formed second insulation film-corresponding to the first region using a predetermined etching process to expose the first insulation film corresponding to the removed part,
wherein an etching selectivity between the first insulation film and the second insulation film is set such that the second insulation film is removed, and the first insulation film remains through the etching process.

2. The method according to claim 1, wherein
the second insulation film is formed of an insulation material identical to that of the first insulation film using a film formation technique different from that of the first embodiment.

3. The method according to claim 1, wherein
the first insulation film is formed by using an atomic layer deposition (ALD) technique when forming the first insulation film, and
the second insulation film is formed by using a plasma chemical vapor deposition (PCVD) technique when forming the second insulation film.

4. The method according to claim 1, wherein the first insulation film is formed using a vacuum ALD technique when forming the first insulation film, and
the second insulation film is formed by using a vacuum CVD technique or a vacuum physical vapor deposition (PVD) technique when forming the second insulation film.

5. The method according to claim 1, further comprising:
forming at least a part of a passive element between the second insulation film and the first insulation film or between the semiconductor substrate and the first insulation film.

6. The method according to claim 5, wherein
at least a part of the passive element is formed over the second insulation film forming at least the part of the passive element.

7. The method according to claim 1, wherein
an etch rate of the second insulation film is higher than that of the first insulation film.

8. The method according to claim 2, wherein
the first insulation film is formed by using an ALD technique when forming the first insulation film, and
the second insulation film is formed by using a PCVD technique when forming the second insulation film.

9. The method according to claim 2, wherein the first insulation film is formed by using a vacuum ALD technique when forming the first insulation film, and
the second insulation film is formed by using a vacuum CVD technique or a vacuum PVD technique when forming the second insulation film.
